(19) United States
(12) Patent Application Publication
(10) Pub. No.: US 2014/0366925 A1
(43) Pub. Date: Dec. 18, 2014

(54) THERMOELECTRIC ELEMENT

(71) Applicants: Eduard Buzetzki, (US); Karl Kirchheimer, (US); Karl Schiller, (US); Franz Padinger, (US)

(72) Inventor: Eduard Buzetzki, Wulkaprodersdorf (AT)

(73) Assignees: Franz Padinger, St. Marien (AT); Karl Schiller, Baumgarten (AT); Eduard Buzetzki, Wulkaprodersdorf (AT); Karl Kirchheimer, Oberwaltersdorf (AT)

(21) Appl. No.: 14/366,400

(22) PCT Filed: Dec. 12, 2012
(86) PCT No.: PCT/AT2012/050193

§ 371 Date: Jul. 21, 2014

(30) Foreign Application Priority Data
Dec. 19, 2011 (AT) A 1841/2011

(51) Int. Cl. H01L 35/32; H02S 10/10

(52) U.S. Cl. CPC H01L 35/32; H01L 31/0583
USPC 136/206; 136/205

(57) ABSTRACT

The invention relates to a thermoelectric element, comprising an electrically conductive carrier layer, an active element, an electrically conductive top layer wherein the carrier layer and the top layer form the outgoing electrode, wherein, in addition, the active element has a p-n junction from an n-type semiconductor to a p-type semiconductor, and wherein the active element is arranged between the carrier layer and the top layer and is electrically conductively connected thereto, and wherein the n-type semiconductor is formed from the group of cyanoferrates. The invention also relates to an energy conversion element comprising a photovoltaic element and a thermoelectric element, wherein the photovoltaic element has an entry side for optical energy and a base surface opposite said entry side, wherein the thermoelectric element is arranged with its carrier layer in thermal contact on the base surface.

The invention relates to a thermoelectric element.

Thermoelectric elements or thermoelectric generators (TEG) are based on the Seebeck effect, according to which electric voltage can be produced when there is a temperature difference along two connected conductors made of different materials. The Seebeck effect is assumed here to be known to a person skilled in the art.

In addition to embodiments of thermoelectric generators as a measuring point or measuring probe, for example in ignition fuses of furnaces, an embodiment is known in the form of a flat element. In this case instead of a combination of metals a combination of semiconductors is used, in terms of structure it resembles a Peltier element. By using semiconductor materials the efficiency can be significantly increased in comparison to thermoelements that are based on metal pairings. In a Peltier element in a known manner semiconductor elements, an n-semiconductor and a p-semiconductor, are connected in series respectively, wherein the series connection bridge is arranged alternately opposite and thus forms a cold and a warm side of a Peltier element. On the formation of a temperature difference between the cold and warm side of the Peltier element, owing to the Seebeck effect, electrical energy is provided at the connection points.

A disadvantage of such TEGs is that the Seebeck effect is based on a temperature difference, the amount of voltage produced becomes greater with an increasing temperature difference up to a maximum value of the temperature difference, so that for the reliable functioning of such an element the greatest possible temperature difference has to be maintained. Therefore one side, the cold side, is mostly cooled by very expensive devices, for example by means of forcibly actuated air cooling and possibly by means of water cooling. Because of this additional cost it is not generally possible to achieve an economical energy recovery by means of TEGs, as the cost of cooling cancels out the advantage achieved by the generation of energy.

A further area of application of thermoelectric generators is anywhere where process heat is available which has to be removed unused into the environment or via cooling systems. For example older generation combustion engines or furnaces have a high exhaust gas temperature, whereby a large proportion of the primary energy used is wasted unused. Also the technical devices can overheat when operated as intended which may have such a negative effect on the operating parameters that the effectiveness of the technical device is reduced. An example of this includes photovoltaic elements, which heat up very significantly during normal operation because of their optimal alignment relative to the sun, whereby operating temperatures of up to 140° can be reached easily. Operating temperatures of this level impair the conversion efficiency of the photovoltaic element, so that particularly in more southern countries the economic use of photovoltaic elements is limited because of the prevailing, high temperatures. Here it would be an advantage if thermal energy could be removed from the photovoltaic element and said thermal energy could be used additionally for producing energy.

Known thermoelectric elements, as already described, have the disadvantage that they are only suitable for producing energy when there is a temperature difference between the two flat sides; for Peltier elements temperature differences of up to 70° C. are achievable/necessary. By arranging known elements on a photovoltaic element the gained energy is used up by the additional effort of cooling the thermoelectric element, so that their economic use is not possible in practice.

Due to its structure as a serial connection of individual semiconductor blocks, the known thermoelectric element has low electrical resistance, but at the same time has very low thermal resistance. This means that with the input of heat on one side the heat flows through the thermoelectric element very rapidly and without a sufficient amount of cooling on the opposite side the temperature is equalized, whereby the flow of heat and thereby also the energy conversion comes to a stop.

The underlying objective of the invention is to create a thin film thermoelectric element (TEE) which is more effective than known TEEs and is simpler and less expensive to produce. Furthermore, the objective of the invention is to configure the thermoelectric element such that the temperature equalization in the element is reduced.

The objective of the invention is achieved by a thermoelectric element (TEE) which comprises an electrically conducting carrier layer, an active element and an electrically conductive cover layer. The carrier layer and the cover layer form the outgoing electrodes; furthermore the active element comprises a p-n-junction from an n-semiconductor to a p-semiconductor. The active element is arranged between the carrier layer and the cover layer and connected to the latter in an electrically conducting manner. The n-semiconductor is formed from the cyanoferrate group, which has the surprising advantage that with materials from this group, arranged at a p-n-junction, a conversion of heat occurs into electrical energy.

Known thermoelectric elements (Peltier or Seebeck elements) have a p-n-junction and known semiconductor materials are for example Bi₂Te₃, PbTe, SiGe, BiSb or FeSi₂. However, said elements are on the one hand very expensive and on the other hand in the desired frequency range of infrared radiation (IR) have a very modest conversion efficiency. In particular, Si-based semiconductors because of their band gap are largely unsuitable only for wavelengths larger than about 1.1 μm, GaSb-based semiconductors can be used up to about 1.5 μm, but are less effective than Si-semiconductors.

In contrast to known semiconductor materials the materials from the cyanoferrate group are much more inexpensive, which means that the economic use of such TEEs is also improved, and no expensive production systems are necessary for processing said materials, in particular no high temperature or high vacuum systems are necessary.

By having an arrangement in which the active element is arranged on the carrier layer and the cover layer is arranged on the active element the cover layer, the active element is protected by the two layers. Furthermore, by means of the two layers an effective thermal coupling is achieved to the environment or a thermal energy source or an equalizing of the thermal energy input is achieved in the carrier or cover layer. Likewise in this way there is a good diversion of the load carrier generated by the active element.

By means of a configuration in which the carrier layer and the cover layer are aligned substantially parallel to one another, a flat device is formed which can be attached very easily to a thermal energy source and thereby enables a good thermal connection to the energy source. In particular, in this way thermal energy can be taken from a source over a large area.

In known thermoelectric elements the semiconducting materials are arranged next to one another in blocks and are connected respectively on the end face side to a series connection, whereby the respective end face sides of all of the blocks form the two flat sides of such an element. The structure of a known TEE is considered here to be known to a person skilled in the art. This known plane arrangement has the advantage of low electrical resistance and at the same time the thermal resistance is also low. Therefore, the temperature equalizes over the thickness of the semiconductor blocks and the energy conversion ceases—as the latter is based on a temperature difference between the semi-conductor transitions. Therefore, in such elements a temperature difference has to be maintained over the thickness of the semiconductor blocks—one side is generally cooled very expensively which significantly reduces the overall efficiency. An arrangement according to the invention in which the active element is configured as a layered structure (cross plane) now has the advantage that in this way the thermal resistance increases significantly over the thickness of the layered structure, so that there is only a small temperature equalization and thus the TEE does not need addition cooling.

The layered structure is preferably built up so that the p-semiconductor is arranged on the carrier layer. The n-semiconductor is arranged on top over which the cover layer is arranged.

According to one development the n-semiconductor is formed by hexacyanoferrate.

Preferably, the n-semiconductor is made from iron(III)-hexacyanoferrate(II/III) (Fe₇C₁₈N₁₈).

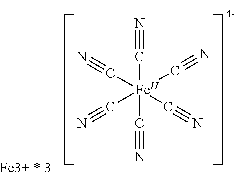

Iron-hexacyanoferrate is known as a dye by the name Prussian blue. It is surprising that this dye as an n-semiconductor in a p-n-junction of an active element can convert heat into electrical energy—similar to the Seebeck effect. By means of the cage-like structure of the hexa-cyanoferrate anion when supplying thermal energy it may occur than the iron in the anion tries to perform a disordered movement (oscillation), but this movement is hindered by the C—N-cage. This hindrance has an effect on the thermal transport, therefore the thermal resistance increases and there is no, or only a much reduced temperature equalization in the active element. The charge carriers released by the input of temperature to the cation of the cyanoferrate complex are caught by the p-layer, which functions as an acceptor (hole transporter), via the electrically conductive carrier and cover layer the produced charge carriers are transported away from the n- and p-layer.

According to one development the n-semiconductor is doped with a least one substance from the group of metal oxides, for example with TiO₂, thereby achieving an improvement in the conversion efficiency. Of the metal oxides all substances are an advantage, which have a large band gap and/or a surface structure with large pores, in order to achieve the best possible absorption of the incoming thermal energy (IR radiation).

The p-semiconductor can be made from a material from the group PEDOT:PSS, GaSb/PEDOT and Si. For the silicon nano Si or p-doped Si (e.g. with boron) is possible.

According to one development the carrier layer is formed by a transparent substrate on which a transparent electrode is applied. For example the carrier layer can be formed by glass, plastic, the transparent electrode is preferably in the form of a TCO. Transparent is defined in this context to mean that the relevant wavelength range—from 400 nm to 700 nm—is not damped or is only very slightly damped by the carrier layer or the electrode. This configuration has the further advantage that the carrier layer can be configured to be electrically insulating and thus the attachment of the present TEE is possible on a plurality of materials, in particular electrically conducting materials, without additional protective measures.

In one development according to which the carrier layer is formed by an elastically restorable substrate an element is created which can also be attached without any risk of damaging the TEE on non-planar surfaces. The carrier layer can be formed for example by a PET layer, and a technician would have the specialist knowledge to determine the minimum bending radii of the material, the active element and in particular that of the outgoing electrodes to prevent damage by deformation.

A development in which the carrier layer and/or the cover layer is formed by a metal conductor has the advantage that the charge carriers can be effectively discharged. Furthermore, a metal conductor mostly has good thermal conductivity, whereby temperature equalization is possible over the carrier and/or the cover layer and the latter therefore have a uniform temperature. This has the advantage that in the active element there are no equalization currents (thermal and/or electric), which increases the overall efficiency in particular. In an advantageous development it is the case that for example the n-semiconductor is applied directly onto the carrier layer which thus takes on the support function and the charge carrier discharge.

Furthermore, in one development the carrier layer is formed by a collector layer made of tungsten carbide for example. In this way it is achieved in an advantageous manner that incoming IR-radiation is converted by the collector layer into convection heat which subsequently has an impact on the active element. The collector layer can be configured selectively for example for a wavelength range in order despite a low level of incoming radiation to absorb as much energy as possible and transfer it to the active element. In one possible development the present TEE can be used in an environment where only a portion of the infrared spectrum is available and the energy content in this spectral range would be too low to have a direct impact on the active element. Here a significant increase in the effectiveness can be achieved by means of a frequency-selective collector.

Furthermore, according to one development the carrier layer and/or the cover layer is/are formed by an electrically conducting grid structure. It is achieved in this way that the proportion of the area of the active element is reduced which is covered by the outgoing electrodes and thus a greater area is available for the action of the IR-radiation. By means of the discharge grid however a sufficiently effective discharge of the charge carrier is ensured.

To protect the active element, in particular from moisture and oxygen, a protective layer is applied over sections of the active element which are not covered by the carrier layer and the cover layer. Said protective layer can be formed for example by glass, by a plastic film which can be coated with aluminum or boron nitrite for example to reduce the moisture and oxygen permeability, or by a metallized film Moisture and/or oxygen in particular can cause slowly progressing, irreversible damage to the semiconductor materials of the active element which could cause the failure of the active element.

According to one development on the side of the carrier layer and/or the cover layer averted from the active element a protective layer is applied. As the two layers form the outgoing electrodes it is an advantage for the application safety if the protective layer is configured to be electrically insulating for example in the form of a plastic film made of PET, PVA, PVC, PC, to name only the most important materials. Furthermore, the protective layer can also be configured to protect the layers and in particular the whole TEE from environmental influences at the site of operation.

According to one embodiment the active element of the present thermoelectric element has a thickness in the range of 1 μm to 1 mm, preferably in the range of 10 μm to 50 μm. In this way a TEE is created which has a very small overall thickness—and thereby a low weight—and thus can be very easily attached to existing devices.

According to one possible configuration for increasing the emitted electrical voltage at least one further active element is arranged on the cover layer with a cover layer on top. In this development the cover layer of the lower TEE represents the carrier layer of the TEE arranged on top, this thus consists of a structurally determined, hard-wired serial connection of a plurality of TEEs, the electrical energy tapped from the lower carrier layer and the upper cover layer. This arrangement corresponds to a stack structure, wherein the terms bottom and top describe the arrangement of the respective element in said stack structure.

A further possible configuration for increasing the energy output is to provide a repeat structure consisting of a layered carrier layer, active element and cover layer. Between the cover layer and the carrier layer of the next TEE arranged thereon an insulating layer can be provided or the cover layer and/or the carrier layer can be configured to be electrically insulating in order to prevent an electrical connection of the stacked TEEs. By means of this arrangement no electrical wiring is provided, in particular the outgoing electrodes of the individual TEEs are guided outwards and thus can be wired externally as desired, so that any desired series and/or parallel circuit can be formed. In particular, the voltage level and the current output capacity can be adjusted to the desired incidence of use.

As the materials used enable very simple processing, in particular application is possible by means of a printing method, in an advantageous manner a multi-layered system can be built up which comprises a plurality of active elements applied on top of one another or arranged on top of one another. As the outgoing electrodes can be produced in a printing method, a plurality of TEEs can also be printed on top of one another. For example arrangements are possible with 10 or more layers.

The objective of the invention is also achieved by an energy conversion element which comprises a photovoltaic element and the present thermoelectric element. The photovoltaic element has an entry side for optical energy and a base surface opposite the latter. The thermoelectric element is arranged with its carrier layer in thermal contact with the base surface. A photovoltaic element is heated very strongly by the sun radiation and this heating possibly reduces the effectiveness of the photovoltaic element, as the conversion properties are temperature-dependent. By means of the present configuration on the one hand the photovoltaic element is cooled and furthermore the energy previously lost as waste heat is also converted into electrical energy. In this way an increase in the total efficiency is achieved of about 2% compared to a pure photovoltaic conversion.

As the parameters of the photovoltaic element and the thermoelectric element do not coincide, the present TEE delivers about 1.2V, a silicon photovoltaic element typically delivers 0.5V, the outgoing electrodes of the photovoltaic element and the outgoing electrodes of the thermoelectric element are connected via a voltage converter to an electric contact section. Thus it is possible for the user to obtain an element which provides electrical energy at a contact section.

For subsequent arrangement on an existing photovoltaic element or for simplifying the manufacturing a development is advantageous in which the thermoelectric element is arranged on the photovoltaic-element by means of a tensioning device or a clamping device.

It is also possible for the thermoelectric element to be arranged on the photovoltaic element by means of an adhesive bond. This can be performed for example by an adhesive connection or by laminating, whereby there has to be a good thermal connection between the photovoltaic element and the TEE.

To reduce the heat transfer resistance and/or balance out unevenness on the surface of the photovoltaic element on which the TEE is arranged, it is an advantage if a heat conducting means is arranged between the base surface and the carrier layer.

For a better understanding of the invention the latter is explained in more detail with reference to the following Figures.

In a schematically much simplified representation:

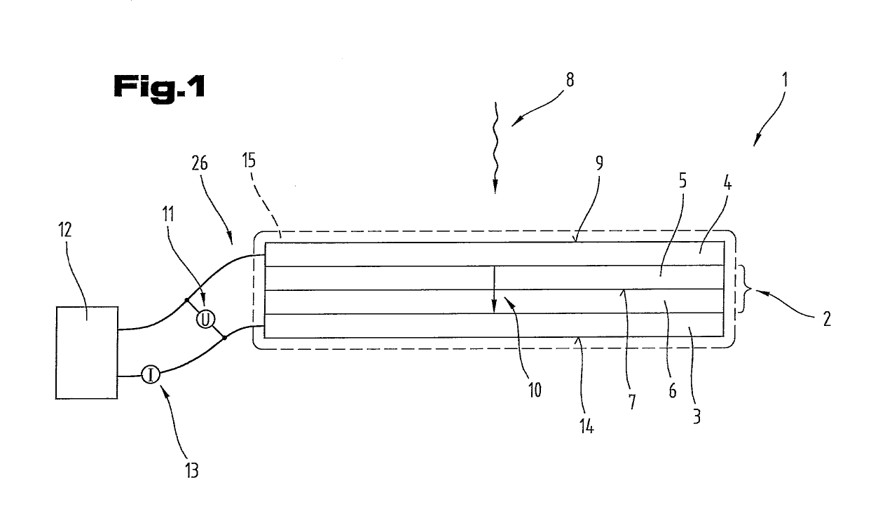

FIG. 1. is an embodiment of the present thermoelectric element;

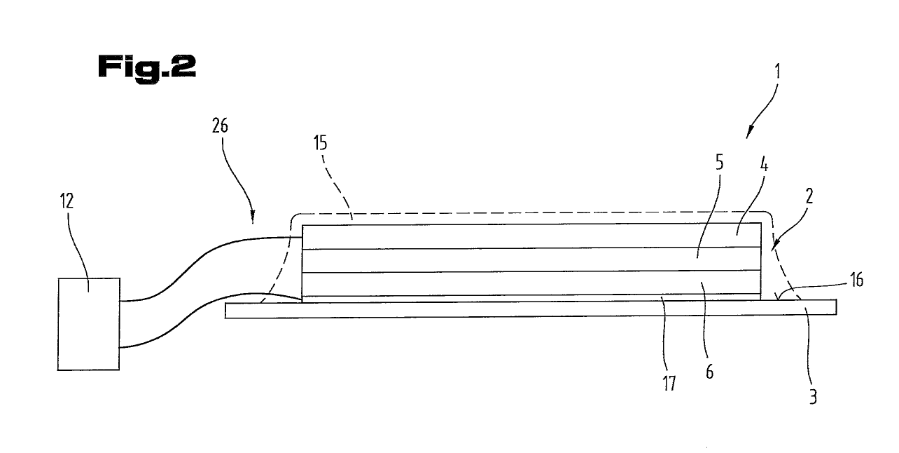

FIG. 2. is a further possible embodiment of the present thermoelectric element;

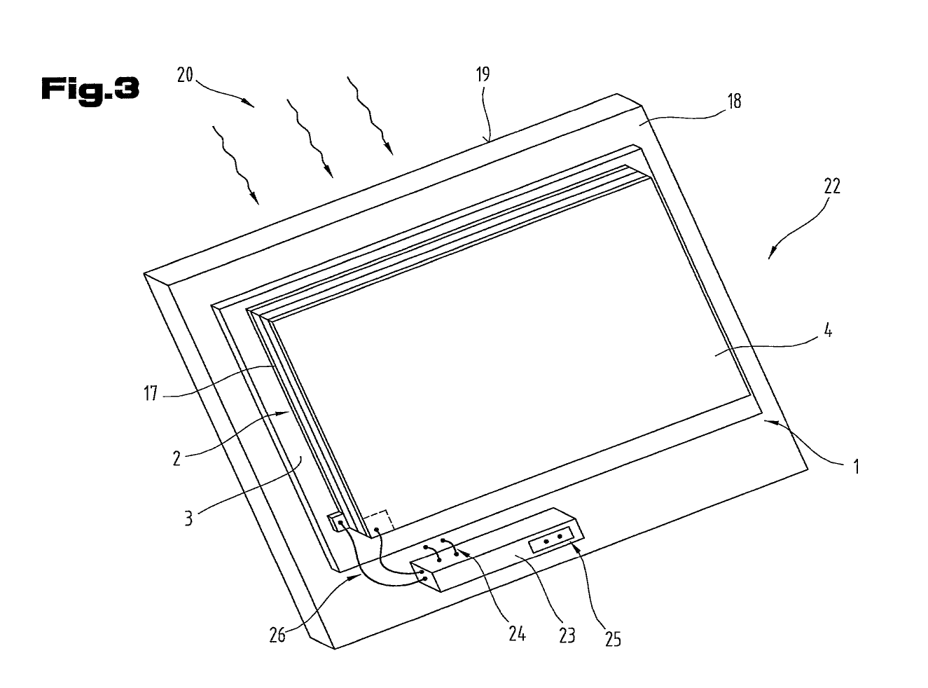

FIG. 3. is an arrangement of the present thermoelectric element on a photovoltaic element;

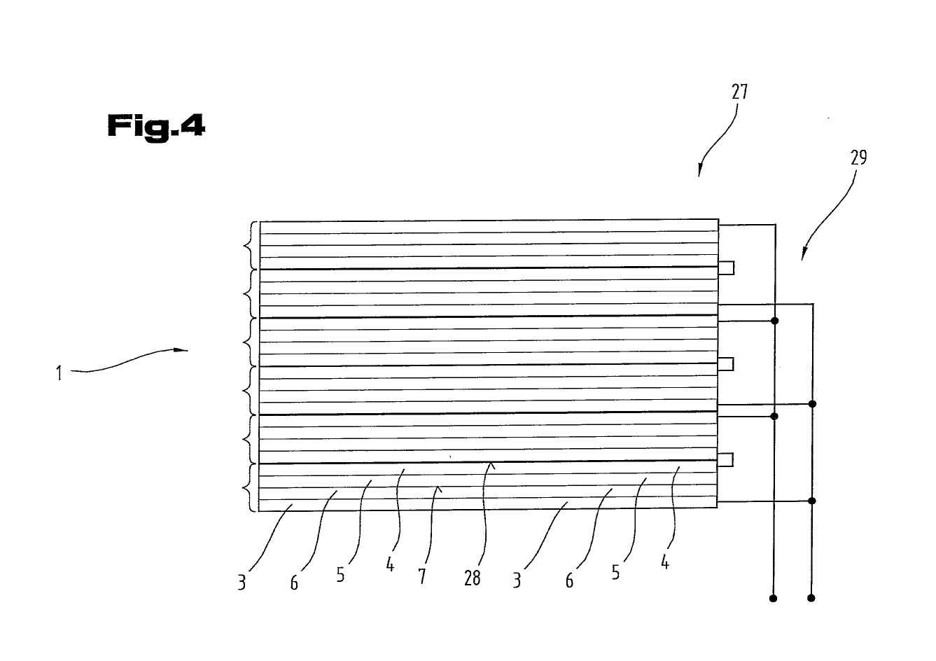

FIG. 4. is a possible development of the TEE for increasing the energy produced by a stack structure.

FIG. 1 shows an embodiment of the present thermoelectric element 1, in which the active element 2 is applied onto the carrier layer 3 and wherein the cover layer 4 is arranged on the active element 2. The active element 2 comprises an n-semiconductor 5 and a p-semiconductor 6 which are adjacent to one another at a p-n-junction 7.

At the same time the carrier layer 3 and the cover layer 4 form the outgoing electrodes, whereby on the impact of thermal energy 8, for example on the flat side 9 of the cover layer 4, on the inside of the thermoelectric element 1, in particular in the active element 2, a temperature gradient 10 is formed. Comparable with the Seebeck effect in the active element a load carrier displacement is formed which can be tapped as electrical voltage 11 by the outgoing electrodes and supplied to a consumer unit 12. By means of the circuit closed via the consumer unit 12 on the impact of thermal energy 8 from the thermoelectric element 1 electrical energy is output so that there is a flow of current 13 in the circuit and the electrical consumer unit 12 can be operated by converting thermal energy 8.

In known thermoelectric elements semiconductor blocks are arranged next to one another, and two semiconductor blocks are connected to one another at the end face via a contact bridge to form a series connection. The structure of a Peltier element is assumed to be known, in particular it is known that a Peltier element has a warm and a cold flat side, wherein the specification of the warm or cold flat side corresponds with the polarity of the electrical voltage at the connector electrodes. As a semiconductor has a low electrical resistance and in particular also has a low thermal resistance, on heating the warm flat side thermal equalization is achieved over the Peltier-element. Without additional expensive measures, in particular without cooling the cold flat side, the temperature of the cold flat side adapts to that of the warm side, whereby the energy conversion comes to a stop. In the present TEE the active element 2 is formed in a so-called cross plane, thus the p-n-junction 7 is located in the path of the temperature gradient 10. This arrangement increases the electrical resistance of the active element 2, but it is a particular advantage that in this way the thermal resistance increases significantly. This means instantly that the thermal equalization currents in the active element 2 are considerably restricted, so that for the present TEE it is not necessary to cool the cold flat side 14.

To protect the whole thermoelectric element 1, but in particular the active element 2, it is possible optionally for the TEE 1 to be surrounded by a protective layer 15, whereby the protective layer 15 is arranged at least in those sections in which the active element 2 is unprotected from the environment by the carrier 3 or cover layer 4. According to one development the carrier 3 or cover layer 4 can also be formed by a grid electrode, so that preferably the protective layer is arranged on the outgoing electrodes 3, 4. The protection of the active element 2 is particularly important as the semiconductors 5, 6 can react chemically on contact with oxygen in the air and/or environmental humidity, which could possibly mean that the desired material properties are lost. The protective layer can be formed for example by glass, a plastic film which can be coated possibly with aluminum or boron nitrite to reduce the permeability of moisture and oxygen, or formed by a metallized film. Said material forms on the one hand good mechanical protection for the thermoelectric element but on the other hand does not disrupts or only disrupts to a small extent the input of thermal energy 8 to the warm flat side 9.

The n-semiconductor 5 of the present thermoelectric element is formed from the group of cyanoferrates, preferably by iron(III)-hexacyanoferrate(II/III). This material is known as the dye Prussian blue, whereby in a surprising manner when using this material as an n-semiconductor in a p-n-junction, an effect comparable to the Seebeck effect is achieved, namely that the impact of temperature on this material combination results in the output of electrical energy via the outgoing electrode 26. Materials from the group of cyanoferrates are on the one hand very inexpensive and can be processed very easily, for example by all of the methods which are suitable for applying a color onto a background. For the p-semiconductor 6 there are hardly any restrictions, as the latter simply have to be used as an acceptor. Preferably, the p-semiconductor is made from a material, which can be processed easily similarly to the n-semiconductor 5 and with respect to mechanical properties is adjusted to those of the carrier 4 or cover layer 3 and the n-semiconductor 5.

FIG. 2 shows a further possible configuration of the present thermoelectric element 1. To configure the carrier layer 3 as an outgoing electrode on a flat side 16 of the carrier layer 3 an electrically conductive electrode 17 is arranged on which electrode 17 the active element 2 is arranged. Preferably, the p-semiconductor 6 is arranged on the electrode 17 and the n-semiconductor 5 is arranged on top, the cover layer 4 is arranged on the n-semiconductor 5 as an outgoing electrode. Similarly it is also possible however for the n-semiconductor to be arranged on the carrier layer, the n-semiconductor on top and the cover layer on top of the latter. This configuration has the advantage for example that the carrier layer 3 can be formed by an electrically insulating material, for example by a plastic film or glass, so that said TEE can be arranged with the carrier layer 3 directly on a thermal energy source, without the user having to be concerned about the electrical insulation of the TEE 1 relative to the thermal energy source. This embodiment has the further advantage, that the carrier layer 3 can be used as a support layer for the subsequently applied layer structure 2. In particular, as the thickness of the active element 2 is preferably below 1 mm, such a thin element conceals the problem that such a thin element can very easily get damaged, even with the outgoing electrodes arranged thereon during further processing or arrangement on thermal energy sources. By having a suitably thick and thereby mechanically stable carrier layer the layer structure arranged thereon can be protected reliably from mechanical loads. With this embodiment it is possible optionally to surround the layer structure consisting of the carrier 3 and cover layer 4 and the active element 2 with a protective layer 15, in order in this way to ensure reliable sealing, in particular of the active element 2, from environmental influences.

FIG. 3 shows a possible use of the present thermoelectric element 1 in combination with a photovoltaic element 18. The photovoltaic element 18 comprises a light inlet side 19 which is preferably aligned at an optimal angle to the sun. Light 20 from the sun hits the light inlet side 19 in a mixture of different wavelengths. For photovoltaic elements 18 it is known that the latter can only convert a portion of the incidental light spectrum 20 into electrical energy. Photovoltaic elements made of polycrystalline or monocrystalline silicon are the most effective compared to other materials or photovoltaic technologies but are limited to wavelengths in the usable spectral range of less than 1400 μm. A large portion of the incidental thermal infrared radiation is lost for energy production but heats the photovoltaic element strongly, whereby temperatures can be reached that are much greater than 100° C. Such strong heating can mean however that the conversion efficiency of the photovoltaic element gets worse, as with an increase in temperature the electrical resistance of each individual photovoltaic converter element also increases.

By arranging the present thermoelectric element 1 preferably on the rear side 21 of the photovoltaic-element 18 the waste heat of the photovoltaic-element 18 can be used and converted into electrical energy. In this way an increase in the overall efficiency of the energy conversion element 22 can increase by at least 1%, whereby increases of up to at least 2% are possible. Compared to the cost necessary to achieve an increase in the efficiency in the region of a tenth of a percent for a photovoltaic element 18, by means of the present configuration a significant increase of the overall efficiency is achieved for a fraction of the cost that makes an increase in efficiency of a photovoltaic-element 18 necessary. In addition to the extra energy production the arrangement of the present thermoelectric element 1 on a photovoltaic-element 18 has the further advantage, that the photovoltaic element 18 is cooled by the energy conversion which is an advantage for the operating parameters and thus the conversion efficiency of the individual photovoltaic converter.

For a user it is an advantage if an energy conversion element 22 provides its energy at a single connection point. As however the generated voltages and mainly the volume of the energy provided between the photovoltaic element 18 and the thermoelectric element 1 differ, the two energy output connections do not connect together directly, it is an advantage if a voltage converter 23 is provided on the energy converting element 22. The latter is connected to the outgoing electrodes 24 of the photovoltaic element 18 and to the outgoing electrodes 26 of the thermoelectric element 1. A voltage converter 23 is able in a known manner to merge together the electrical energy levels of different electrical energy sources and make them available at a common energy output section 25.

For illustrative purposes in the Figures the layer thicknesses of the thermoelectric element 1, in particular the thickness ratios of the carrier 3 and cover layer 4 and the active element 2 are exaggerated. A protective layer arranged if necessary over the layer structure is also not shown in the Figure for illustrative reasons. The thermoelectric element 1 is preferably applied with its carrier layer by adhesion or lamination on the rear side 21 of the photovoltaic element 18, whereby in the case of an adhesive connection the adhesive has to have good thermal conductivity in order to ensure an effective thermal coupling of the TEE to the photovoltaic element 18. Likewise it is the case that between the carrier layer 3 and the rear side 21 of the photovoltaic element 18 a thermal conducting means is provided in order on the one hand to improve the temperature transport and if necessary balance out existing, small bumps on the rear side 21 and ensure a good application of the carrier layer 3 onto the rear side 21.

In the illustrated case the present thermoelectric element 1 is arranged with its carrier layer on the rear side of the thermal energy source, here the photovoltaic-element 18. Likewise, it is also possible for the TEE to be arranged with its cover layer 4 on the rear side. In the shown case the carrier layer 3 is configured as an electrically non-conducting substrate, on which an electrode 17 is arranged, in order to thus form the outgoing electrode. If the TEE is attached with its electrically conducting cover layer 4 on the rear side of the photovoltaic element 18 it has to be ensured that there will be no short circuit or mutual, electrical interference between the TEE 1 and photovoltaic element 18.

In particular by using printing methods it is possible in an inexpensive manner to produce individual TEEs up to a batch size of 1. For example, the finally assembled photovoltaic element can be arranged in a printing device, for example an inkjet printer, and then the thermoelectric element is printed on directly. In this case the individual layers are applied by means of a print head which is guided over the section to be printed. A layered application is possible with a respectively interposed dry step. By means of a corresponding configuration of the print head with a drying device the whole layer structure with the outgoing electrodes can be applied in one pass.

A photovoltaic element 18, in particular each individual photovoltaic converter element, is mostly built up in layers in a known manner, whereby the base substrate mostly forms one of the two outgoing electrodes. A possible development can also be that the outgoing electrode of the photovoltaic converter elements of the photovoltaic element 18 is formed by the electrically conductive carrier 3 or cover layer 4. In said embodiment on the one hand an outgoing electrode can be omitted and furthermore a particularly compact structure can be achieved with very good heat cogeneration of the photovoltaic converter elements on the thermoelectric element 1.

To summarize, the particular advantage of the present thermoelectric element is that by using a very inexpensive material, which is very easy to process a semiconductor element can be formed which emits electrical energy from the effect of temperature. The surprising factor is that materials from the group of cyanoferrates show this effect, similar to the Seebeck-effect, in particular that the preferred iron(III)-hexacyanoferrate(II/III) generally known as a dye shows this effect. In combination with a photovoltaic element on the one hand the overall efficiency is increased significantly by the additional recovery of energy from the waste heat and on the other hand the operating parameters of the photovoltaic element are stabilized.

FIG. 4 shows a possible further embodiment of the present thermoelectric element as a stack structure 27, in which a plurality of TEEs 1 are arranged on top of one another. The Figure shows that on the cover layer 4 of the bottom TEE, a further TEE 1 is arranged with its carrier layer. As the carrier 3 and cover layer 4 respectively can also form the outgoing electrode, it is possible that an electrically insulating layer 28 can be arranged between the two layers. In this way fully independent TEEs are created which are arranged on top of one another and are thus located in the same thermal energy current, but with respect to their electrical wiring are completely free. FIG. 4 shows an electrical wiring network 29, which connects two TEEs in series in order to achieve a higher output voltage. The series connections are connected in parallel to thus increase the output current. In this way by stacking on top of one another the energy obtained can be increased significantly. As an individual TEE can output an electric voltage of up to 1.2V and can output a current of up to 3 A/m² a series or parallel connection is particularly advantageous if in a simple manner the electrical output parameters can be adjusted. For example in order to operate a consumer unit directly or adjust the output voltage if necessary in a downstream voltage converter

According to one development no insulating layer 28 is provided, the cover layer 4 of the lower and the carrier layer 3 of the overlying TEE can thus be in electrical contact. In this case one of the two layers could be omitted, so that the cover layer of the lower element forms the carrier layer of the overlying element. In this case the whole stack structure 27 is connected in series, the output voltage is then tapped from the carrier layer 3 of the bottom element 1 and the cover layer 4 of the top element 1.

Lastly, it should be noted that in the variously described exemplary embodiments the same parts have been given the same reference numerals and the same component names, whereby the disclosures contained throughout the entire description can be applied to the same parts with the same reference numerals and same component names. Also details relating to position used in the description, such as e.g. top, bottom, side etc. relate to the currently described and represented figure and in case of a change in position should be adjusted to the new position. Furthermore, also individual features or combinations of features from the various exemplary embodiments shown and described can represent in themselves independent or inventive solutions.

All of the details relating to value ranges in the present description are defined such that the latter include any and all part ranges, e.g. a range of 1 to 10 means that all part ranges, starting from the lower limit of 1 to the upper limit 10 are included, i.e. the whole part range beginning with a lower limit of 1 or above and ending at an upper limit of 10 or less, e.g. 1 to 1.7, or 3.2 to 8.1 or 5.5 to 10.

The exemplary embodiments show possible embodiment variants of the thermoelectric generator, whereby it should be noted at this point that the invention is not restricted to the embodiment variants shown in particular, but rather various different combinations of the individual embodiment variants are also possible and this variability, due to the teaching on technical procedure, lies within the ability of a person skilled in the art in this technical field. Thus all conceivable embodiment variants, which are made possible by combining individual details of the embodiment variants shown and described, are also covered by the scope of protection.

FIGS. 2 to 4 show a further and possibly independent embodiment of the thermoelectric generator, in which the same reference numbers and components names have been used for the same parts as in the preceding Figures. To avoid unnecessary repetition reference is made to the detailed description of the preceding Figures.

Finally, as a point of formality, it should be noted that for a better understanding of the structure of the thermoelectric generator the latter and its components have not been represented true to scale in part and/or have been enlarged and/or reduced in size.

The underlying objective of the independent solutions according to the invention can be taken from the description.

Mainly the individual embodiments shown in FIGS. 1-3 can form the subject matter of independent solutions according to the invention. The relative problems and solutions of the invention can be taken from the detailed descriptions of these figures.

### LIST OF REFERENCE NUMBERS

1 thermoelectric element (TEE)

2 active element

3 carrier layer, outgoing electrode

4 cover layer, outgoing electrode

5 n-semiconductor

6 p-semiconductor

7 p-n-junction

8 thermal energy

9 flat side, warm

10 temperature gradient

11 electric voltage

12 consumer unit

13 electric current

14 flat side, cold

15 protective layer

16 flat side

17 electrode

18 photovoltaic element

19 light inlet side

20 light

21 base surface, rear side

22 energy conversion element

23 voltage converter

24 outgoing electrodes of the photovoltaic element

25 energy output section

26 outgoing electrodes of the thermoelectric element

27 stack structure

28 insulating layer

29 electric wiring network

1. A thermoelectric element (1), comprising an electrically conductive carrier layer (3), an active element (2), an electrically conductive cover layer (4), the carrier layer (3) and the cover layer (4) forming the outgoing electrodes, furthermore the active element (2) comprising a p-n-junction (7) of an n-semiconductor (5) to a p-semiconductor (6) and the active element (2) being arranged between the carrier layer (3) and the cover layer (4) and connected in an electrically conductive manner, wherein the n-semiconductor (5) is formed from the group of cyanoferrates.

2. The thermoelectric element as claimed in claim 1, wherein the active element (2) is arranged on the carrier layer (3) and the cover layer is arranged (4) on the active element (2).

3. The thermoelectric element as claimed in claim 1, wherein the carrier layer (3) and the cover layer (4) are aligned essentially parallel to one another.

4. The thermoelectric element as claimed in claim 1, wherein the active element (2) is configured to have a layered structure.

5. The thermoelectric element as claimed in claim 4, wherein the p-semiconductor (6) is arranged on the carrier layer (3).

6. The thermoelectric element as claimed in claim 1, wherein the n-semiconductor (5) is formed by hexacyanoferrate.

7. The thermoelectric element as claimed in claim 6, wherein the n-semiconductor (5) is formed by iron (III)-hexacyanoferrate(II/III).

8. The thermoelectric element as claimed in claim 6, wherein the n-semiconductor (5) is doped with at least one substance from the group of metal oxides, for example with TiO₂, Si—P, GaAs, InSb, CdS, ZnSe, Ge, Te, Al₂O₃, Fe₂O₃.

9. The thermoelectric element as claimed in claim 1, wherein the p-semiconductor (6) is formed from one of the group PEDOT:PSS, GaSb/PEDOT and Si.

10. The thermoelectric element as claimed in claim 1, wherein the carrier layer (3) is formed by a transparent substrate onto which a transparent electrode is applied.

11. The thermoelectric element as claimed in claim 1, wherein the carrier layer (3) is formed by an elastically restorable substrate.

12. The thermoelectric element as claimed in claim 1, wherein the carrier layer (3) and/or the cover layer (4) is formed by a metal conductor.

13. The thermoelectric element as claimed in claim 1, wherein the carrier layer (3) is formed by a collector layer.

14. The thermoelectric element as claimed in claim 1, wherein the carrier layer (3) and/or the cover layer (4) is formed by an electrically conductive grid structure.

15. The thermoelectric element as claimed in claim 1, wherein a protective layer (15) is applied over the sections of the active element (2) which are not covered by the carrier layer (3) and the cover layer (4).

16. The thermoelectric element as claimed in claim 1, wherein a protective layer (15) is applied onto the side of the carrier layer (3) and/or the cover layer (4) facing away from the active element (2) respectively.

17. The thermoelectric element as claimed in claim 1, wherein the active element (2) has a thickness in a range of 10 μm to 1 mm, preferably in a range of 10 μm to 50 mm.

18. The thermoelectric element as claimed in claim 1, wherein on the cover layer (4) at least one further active element (2) with a cover layer is arranged.

19. The thermoelectric element as claimed in claim 1, wherein a repeated structure consisting of a carrier layer, active element and cover layer is provided arranged on top of one another.

20. An energy conversion element (22) comprising a photovoltaic element (18) and a thermoelectric element (1) as claimed in claim 1, the photovoltaic element (18) having an inlet side (19) for optical energy (20) and a base surface (21) opposite the latter, wherein the thermoelectric element (1) with its carrier layer (3) is arranged in thermal contact on the base surface (21).

21. The energy conversion element as claimed in claim 20, wherein the photovoltaic element (18) delivers its generated electrical energy via outgoing electrodes (24), wherein the outgoing electrodes (24) of the photovoltaic element (18) and the outgoing electrodes (26) of the thermoelectric element (1) are connected by a voltage converter (23) to an electric contact section (25).

22. The energy conversion element as claimed in claim 20, wherein the thermoelectric element (1) is arranged by means of a tensioning device or a clamping device on the photovoltaic element (18).

23. The energy conversion element as claimed in claim 20, wherein the thermoelectric element (1) is arranged by means of an adhesive connection to the photovoltaic element (18).

24. The energy conversion element as claimed in claim 20, wherein between the base surface (21) and the carrier layer (3) a heat conducting means is arranged.
